(19) United States
(12) Patent Application Publication
(10) Pub. No.: US 2022/0302169 A1
(43) Pub. Date: Sep. 22, 2022

(54) SEMICONDUCTOR STORAGE DEVICE

(71) Applicant: KIOXIA CORPORATION, Tokyo (JP)

(72) Inventors: Keisuke TAKAGI, Nagoya Aichi (JP); Kazuhiro MATSUO, Kuwana Mie (JP); Kunifumi SUZUKI, Yokkaichi Mie (JP); Yuuichi KAMIMUTA, Yokkaichi Mie (JP); Taro SHIOKAWA, Nagoya Aichi (JP); Masumi SAITOH, Yokkaichi Mie (JP); Yuta KAMIYA, Nagoya Aichi (JP); Kota TAKAHASHI, Yokkaichi Mie (JP)

(21) Appl. No.: 17/411,733

(22) Filed: Aug. 25, 2021

(30) Foreign Application Priority Data
Mar. 16, 2021 (JP) 2021-042328

(51) Int. Cl. H01L 27/11597; G11C 16/04; H01L 27/1157; H01L 27/11582

(52) U.S. Cl. CPC H01L 27/11597; G11C 16/0483; H01L 27/1157; H01L 27/11582

(57) ABSTRACT

A semiconductor storage device includes a channel layer extending along a first direction and including titanium oxide, an electrode layer extending along a second direction crossing the first direction, and a ferroelectric layer between the channel layer and the electrode layer and including titanium.

### CROSS-REFERENCE TO RELATED APPLICATION(S)

This application is based upon and claims the benefit of priority from Japanese Patent Application No. 2021-042328, filed Mar. 16, 2021, the entire contents of which are incorporated herein by reference.

### FIELD

Embodiments described herein relate generally to a semiconductor storage device.

### BACKGROUND

A semiconductor storage device using spontaneous polarization of a ferroelectric layer has attracted attention. In such a semiconductor storage device, a value of a threshold voltage necessary for bringing a channel into a conduction state changes according to the degree of the spontaneous polarization. By using such a property of the ferroelectric layer, data can be stored in memory cells.

### BRIEF DESCRIPTION OF THE DRAWINGS

FIG. 1 is a diagram showing an equivalent circuit of a semiconductor storage device according to a first embodiment.

FIG. 2 is a schematic diagram of a semiconductor storage device according to a first embodiment.

FIG. 3 is a cross-sectional view of a semiconductor storage device according to a first embodiment.

FIG. 4 is a cross-sectional view of a semiconductor storage device according to a first embodiment.

FIG. 5 is a graph of a threshold voltage.

FIGS. 6A and 6B depict a charge trap in a ferroelectric layer.

FIG. 7 depicts a band gap in each of a ferroelectric layer and a channel layer.

FIG. 8 depicts an energy band in and in the vicinity of a ferroelectric layer.

FIGS. 9A to 9D depict a method for manufacturing a semiconductor storage device according to a first embodiment.

FIG. 10 depicts a leakage current in a ferroelectric layer.

FIG. 11 depicts a relationship between a content of titanium and a spontaneous polarization amount in a ferroelectric layer.

FIG. 12 is a cross-sectional view of a semiconductor storage device according to a second embodiment.

FIG. 13 depicts a distribution of a content of titanium in a ferroelectric layer.

FIG. 14 is a cross-sectional view of a semiconductor storage device according to a third embodiment.

FIG. 15 is a cross-sectional view of a semiconductor storage device according to a fourth embodiment.

### DETAILED DESCRIPTION

Embodiments provide a semiconductor storage device having improved durability.

In general, according to one embodiment, a semiconductor storage device includes a channel layer extending along a first direction and including titanium oxide, an electrode layer extending along a second direction crossing the first direction, and a ferroelectric layer between the channel layer and the electrode layer and including titanium.

Hereinafter, certain embodiments will be described with reference to accompanying drawings. In order to facilitate understanding of the description, the same components are denoted by the same reference numerals in the respective drawings, and redundant description will be omitted.

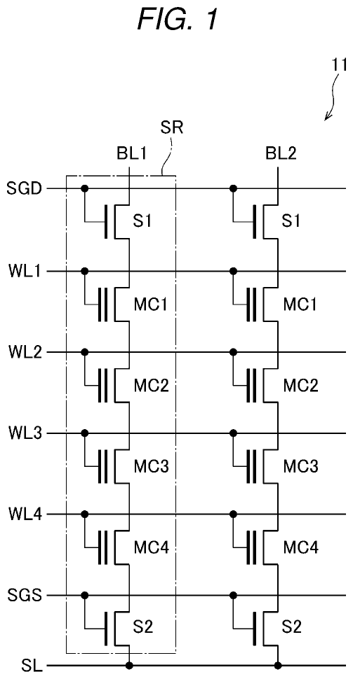

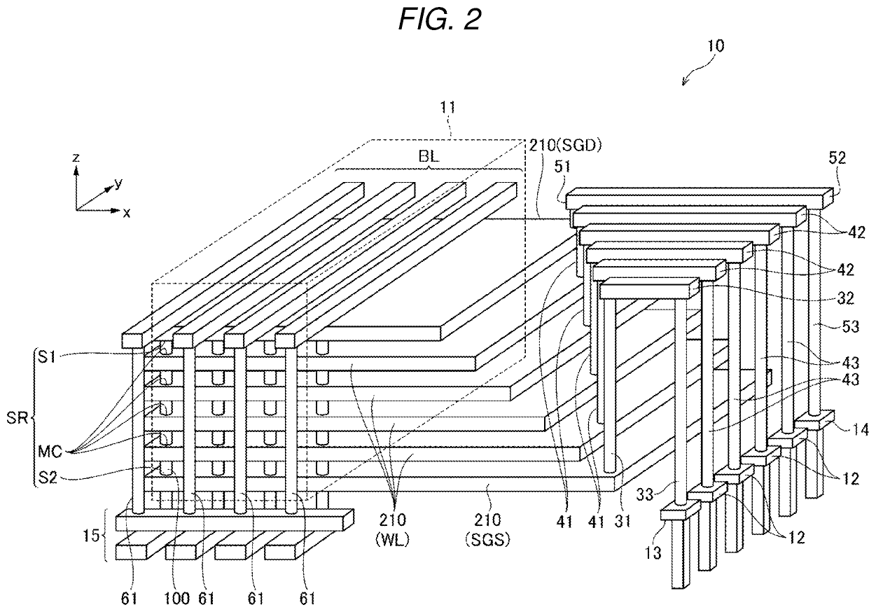

A semiconductor storage device 10 according to a first embodiment is a nonvolatile storage device utilizing a ferroelectric layer. FIG. 1 shows an equivalent circuit diagram of a memory cell array 11 in the semiconductor storage device 10. Further, a schematic diagram of the semiconductor storage device 10 including the memory cell array 11 will be described later with reference to FIG. 2.

As shown in FIG. 1, the memory cell array 11 includes a plurality of NAND strings SR. Each NAND string SR includes, for example, a plurality of memory cells MC and two select transistors S1 and S2. Further, FIG. 1 shows four memory cells MC (MC1 to MC4), but the number of memory cells MC in the NAND string SR may be different from that in the example of FIG. 1.

A plurality of bit lines BL are provided in the memory cell array 11. Further, FIG. 1 shows only two bit lines BL (BL1 and BL2), but the number of bit lines BL may be different from that in the example of FIG. 1.

The plurality of memory cells MC in the NAND string SR are connected in series between a source of the select transistor S1 and a drain of the select transistor S2. A drain of the select transistor S1 is connected to one of the bit lines BL. A source of the select transistor S2 is connected to a common source line SL.

Each memory cell MC is a transistor having a ferroelectric layer in a gate portion. A direction and a magnitude of spontaneous polarization generated in the ferroelectric layer corresponds to the data value stored in the memory cell MC.

Among the memory cells MC in the NAND string SR, one or more memory cells MC provided closer to the select transistor S1 or closer to the select transistor S2 may be treated as dummy cells which are not themselves used for data storage. As in the present embodiment, the dummy cells may be omitted.

Gates of the plurality of select transistors S1 in the memory cell array 11 are all connected to a select gate line SGD. The select gate line SGD is a wiring or conductor to which a voltage is applied for turning on/off of the select transistors S1. In this context, “turning on/off” refers to making a transistor conductive or non-conductive along its source-drain path.

Gates of the plurality of select transistors S2 in the memory cell array 11 are all connected to a select gate line SGS. The select gate line SGD is a wiring or conductor to which a voltage is applied for turning on/off the select transistors S2.

The gates of memory cells MC (MC1 to MC4) are connected to respective word lines WL (WL1 to WL4). Each word line WL is a wiring or conductor to which a voltage can be applied for turning on/off of each memory cell MC, changing a spontaneous polarization amount of the ferroelectric layer in the memory cell MC, and the like.

As a specific method for writing, reading, and erasing data to and from each memory cell MC, various known methods may be used.

A configuration of the semiconductor storage device 10 including the memory cell array 11 will be described with reference to FIG. 2. Hereinafter, an arrangement and the like of each component will be described with reference to an x direction, a y direction, and a z direction shown in FIG. 2.

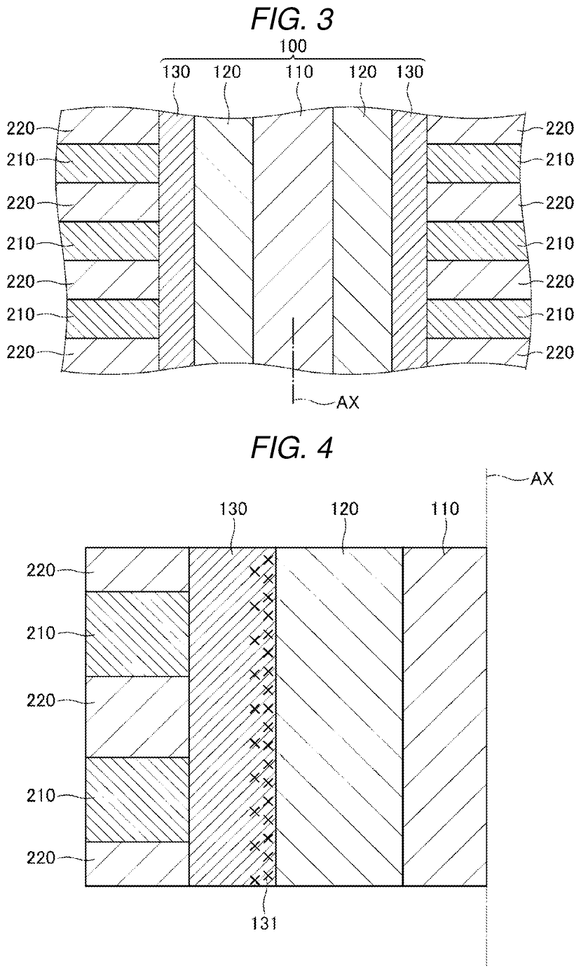

As shown in FIG. 2, in the memory cell array 11, a plurality of electrode layers 210 each having a flat plate shape are provided, and the electrode layers 210 are stacked and disposed at intervals so as to be arranged along the z direction. An insulating layer 220 (see FIG. 3) is disposed between the electrode layers 210 adjacent to each other, but the insulating layer 220 is not shown in FIG. 2. The number of the electrode layers 210 stacked along the z direction may be different from that in the example shown in FIG. 2.

The electrode layer 210 is formed of a conductive material, e.g., tungsten, titanium nitride, or a compound thereof. The electrode layer 210 may be formed of polysilicon to which an impurity is added. In the present embodiment, the electrode layer 210 is formed of titanium nitride.

The insulating layers 220 alternately stacked together with the electrode layers 210 are formed of an insulating material, e.g., silicon oxide and the like.

In the memory cell array 11, a plurality of columnar memory pillars 100 are provided. Each of the memory pillars 100 extends along the z direction so as to penetrate the plurality of electrode layers 210 and the insulating layers 220 described above. One end of the memory pillar 100 is connected to a bit line BL. The other end of the memory pillar 100 is electrically connected to a source line SL (not shown in FIG. 2). Portions of the memory pillar 100 intersecting the stacked electrode layers 210 function as the memory cells MC and the select transistors S1 and S2 described above. In the example of FIG. 2, the uppermost electrode layer 210 in the z direction functions as the select gate line SGD of FIG. 1. Further, the lowermost electrode layer 210 in the z direction functions as the select gate line SGS in FIG. 1. The plurality of electrode layers 210 disposed between the select gate line SGD and the select gate line SGS function as the word lines WL (WL1 to WL4) in FIG. 1.

The plurality of bit lines BL are provided above the uppermost electrode layer 210 in the z direction. The bit lines BL extend along the y direction and are arranged along the x direction. The number of the bit lines BL may be different from that in the example shown in FIG. 2. The upper end portions in the z direction of the plurality of memory pillars 100 arranged along the y direction are connected to one of the bit lines BL.

Each bit line BL is connected to a sense amplifier 15 via a contact 61. The sense amplifier 15 is a control circuit for applying a voltage to each bit line BL or reading the voltage applied to each bit line BL.

Each of the electrode layers 210 extends from the memory cell array 11 toward the +x direction. The electrode layers 210 are formed in a stepped shape on the x direction side of the memory cell array 11. Specifically, the lower electrode layers 210 in the z direction are drawn out so as to extend more toward the +x direction side. Accordingly, a part of each electrode layer 210 is exposed toward the +z direction side. With such a configuration, it is possible to connect a contact 31 and the like to each of the electrode layers 210 and to individually apply a voltage.

The lowermost electrode layer 210 in the z direction, that is, the electrode layer 210 functioning as the select gate line SGS is connected to a gate line drive circuit 13 via the contact 31, an upper side wiring 32, and a contact 33. The gate line drive circuit 13 is a control circuit for applying the voltage to the select gate line SGS.

The uppermost electrode layer 210 in the z direction, that is, the electrode layer 210 functioning as the select gate line SGD is connected to a gate line drive circuit 14 via a contact 51, an upper side wiring 52, and a contact 53. The gate line drive circuit 14 is a control circuit for applying the voltage to the select gate line SGD.

The plurality of electrode layers 210 disposed between the select gate line SGS and the select gate line SGD, that is, the plurality of electrode layers 210 functioning as the word lines WL are each connected to a word line drive circuit 12 via a contact 41, an upper side wiring 42, and a contact 43. The word line drive circuit 12 is a control circuit for applying the voltages to the word lines WL.

An internal structure of the memory pillar 100 will be described with reference to FIG. 3. FIG. 3 schematically shows a cross section of the memory pillar 100 and a portion in the vicinity of the memory pillar 100 taken along a plane including the central axis AX of the memory pillar 100. As shown in the figure, the memory pillar 100 includes a core portion 110, a channel layer 120, and a ferroelectric layer 130.

The core portion 110 is a layer disposed in the central portion of the memory pillar 100, and is formed of an insulating material such as silicon oxide.

The channel layer 120 is a semiconductor layer that covers the outer peripheral surface of the core portion 110. In the first embodiment, the channel layer 120 is formed of a material containing titanium oxide. The channel layer 120 functions as a channel of the memory cells MC and the select transistors S1 and S2. The channel layer 120 may be disposed without providing the core portion 110 in the central portion of the memory pillar 100. One end of the channel layer 120 is electrically connected to one of the bit lines BL, and the other end of the channel layer 120 is electrically connected to the source line SL.

The ferroelectric layer 130 is a layer that covers the outer peripheral surface of the channel layer 120. The ferroelectric layer 130 is formed of a material including a ferroelectric material. As such a ferroelectric material, for example, an oxide containing hafnium such as hafnia (HfO₂) (hafnium dioxide) or an oxide containing zirconium such as zirconia (ZrO₂) (zirconium dioxide) may be used. The ferroelectric material of the ferroelectric layer 130 may be an oxide containing both hafnium and zirconium. In the first embodiment, the ferroelectric layer 130 is formed of the ferroelectric material containing hafnia as a main raw material. The ferroelectric layer 130 has an orthorhombic crystal structure. The crystal structure of the ferroelectric layer 130 may be orthorhombic in the entire structure or may be orthorhombic only in a part thereof.

As shown in FIG. 3, the plurality of stacked electrode layers 210 are connected to the outer peripheral surface of the ferroelectric layer 130. As described above, each of the portions of the memory pillar 100 intersecting the stacked electrode layers 210 function as a memory cell MC or a transistor such as the select transistors S1 and S2 in FIG. 1. When a high voltage is applied to the electrode layer 210, the direction and the magnitude of the spontaneous polarization in the ferroelectric layer 130 change according to the voltage value thereof. Hereinafter, these parameters are collectively referred to as a “spontaneous polarization amount” of the ferroelectric layer 130. The spontaneous polarization amount corresponds to the data stored in the memory cell MC.

When the voltage equal to or higher than a threshold voltage is applied to the gate of the memory cell MC via the electrode layers 210, the channel layer 120 located inside the electrode layers 210 is in a conduction state. The threshold voltage described above changes according to the spontaneous polarization amount. By using this characteristic, the data stored in the memory cell MC can be read.

As described above, the semiconductor storage device 10 according to the present embodiment includes the ferroelectric layer 130 formed of the material including the ferroelectric material, the channel layer 120 formed of the material containing titanium oxide and disposed at a position adjacent to the ferroelectric layer 130, and the electrode layers 210 formed of the conductive material and disposed at a position opposite to the channel layer 120 with the ferroelectric layer 130 interposed therebetween.

A further specific configuration inside the memory pillar 100 will be described with reference to FIG. 4. FIG. 4 only shows a portion on one side of the central axis AX in the cross section showing the internal structure of the memory pillar 100. As shown in FIG. 4, the ferroelectric layer 130 contains titanium 131. That is, the ferroelectric layer 130 in the present embodiment is formed of a material containing the titanium 131 dopants within the hafnia bulk material of the ferroelectric layer 130.

However, the titanium 131 is not uniformly distributed through the entire ferroelectric layer 130, and is distributed in a manner biased to the channel layer 120 side. That is, in the ferroelectric layer 130, a concentration of the titanium 131 in a portion on the channel layer 120 side (a right side in FIG. 4) is higher than a concentration of the titanium 131 in a portion on the electrode layer 210 side (a left side in FIG. 4). Further, in FIG. 4, the titanium 131 is shown in a manner distributed only in the portion of the ferroelectric layer 130 on the channel layer 120 side, but the amount of the titanium 131 contained in the portion of the ferroelectric layer 130 on the electrode layer 210 side may not be 0.

The concentration of the titanium 131 contained in the ferroelectric layer 130 gradually increases from the electrode layer 210 side toward the channel layer 120 side. Instead of such a mode, the concentration of the titanium 131 may change in a stepwise manner from the electrode layer 210 side to the channel layer 120 side. Here, the “concentration of the titanium 131” is the number of atoms of the titanium 131 contained per unit volume of the ferroelectric layer 130.

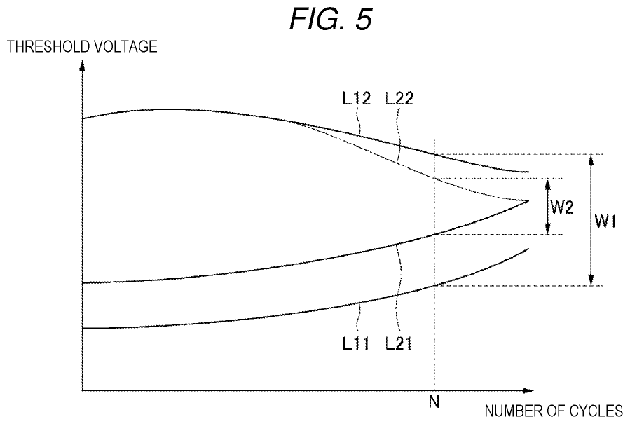

An effect of the titanium 131 contained in the ferroelectric layer 130 will be described with reference to FIG. 5. The horizontal axis of a graph shown in FIG. 5 represents the number of cycles when the data is repeatedly written to and erased from the memory cell MC. The vertical axis of the graph represents the threshold voltage of the memory cell MC, that is, a value of the voltage to be applied in order to bring the channel layer 120 into the conduction state.

Lines L21 and L22 in FIG. 5 represent changes in a threshold voltage in a semiconductor storage device according to a comparative example. In the comparative example, the ferroelectric layer does not contain titanium.

The line L21 represents the change in the threshold voltage in a state where the data is written into the memory cell MC of the comparative example, and the line L22 represents the change in the threshold voltage in a state where the data is erased from the memory cell MC of the comparative example.

A difference between the threshold voltage in the erased state represented by the line L22 and the threshold voltage in the write state represented by the line L21 is referred to as a “memory window”. As is well known, in a semiconductor storage device having a configuration using the ferroelectric material, it is preferable to ensure a wide memory window in order to stably read and write the stored data. However, as shown in FIG. 5, when the writing and the erasing of the data to and from the memory cell MC are repeatedly performed, the memory window is likely to become gradually narrower. In the example of FIG. 5, at a time point at which the number of cycles on the horizontal axis is N, a value of the memory window in the comparative example is W2. When the value of the memory window becomes too narrow, it becomes difficult to stably read and write the data in the semiconductor storage device.

Lines L11 and L12 in FIG. 5 represent changes in the threshold voltage in the semiconductor storage device 10 according to the first embodiment. That is, the lines L11 and L12 represent the changes in the threshold voltage when the ferroelectric layer 130 contains the titanium 131. The line L11 represents the change in the threshold voltage in a state where the data is written into the memory cell MC of the first embodiment, and the line L12 represents the change in the threshold voltage in a state where the data is erased from the memory cell MC of the first embodiment.

As is clear from comparison with the comparative example, the memory window of the first embodiment is kept wider than in the comparative example from the beginning. Further, the change in the memory window when the writing and the erasing of the data to and from the memory cell MC are repeated is reduced as compared to the case of the comparative example. For example, the value of the memory window at the time point at which the number of cycles on the horizontal axis is N is W1 which is larger than W2.

As described above, in the semiconductor storage device 10, because of the ferroelectric layer 130 containing the titanium 131, a wide memory window can be provided and maintained. Accordingly, durability (lifetime) of the semiconductor storage device 10 is improved.

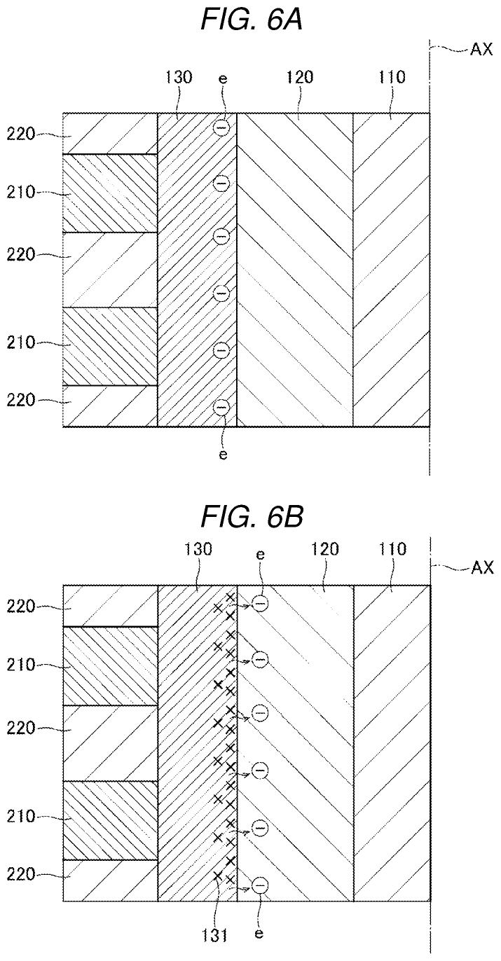

In FIG. 6A, the semiconductor storage device according to the comparative example is drawn from the same viewpoint as in FIG. 4. As shown in FIG. 6A, in the semiconductor storage device according to the comparative example, when the writing and the erasing of the data to and from the memory cell MC are repeatedly performed, a phenomenon called “charge trap” occurs, and electrons “e” are trapped in the ferroelectric layer 130. The phenomenon in which the memory window is gradually narrowed as described with reference to FIG. 5 is presumed to be caused by increase of the electrons “e” trapped in the ferroelectric layer 130 by the charge trap.

When, for example, polysilicon and the like is used as the material of the channel layer as in a configuration in the related art, the above-described charge trap is particularly likely to occur. It is considered that this is because an oxide film is formed between the channel layer and the ferroelectric layer, and thus the electrons “e” are more likely to be accumulated. As in the comparative example described above, when titanium oxide is used as the material of the channel layer, the oxide film is not formed, and therefore the charge trap can be reduced to some extent. However, it is difficult to sufficiently reduce the charge trap by simply replacing the material of the channel layer with titanium oxide.

In contrast, in the configuration in which the ferroelectric layer 130 contains the titanium 131 as in the semiconductor storage device 10, the electrons “e” are likely to move from the ferroelectric layer 130 to the channel layer 120 as shown in FIG. 6B. Therefore, the amount of the electrons “e” trapped in the ferroelectric layer 130 can be reduced as compared to the related art, and as a result, a wide state of the memory window can be maintained for a longer period of time.

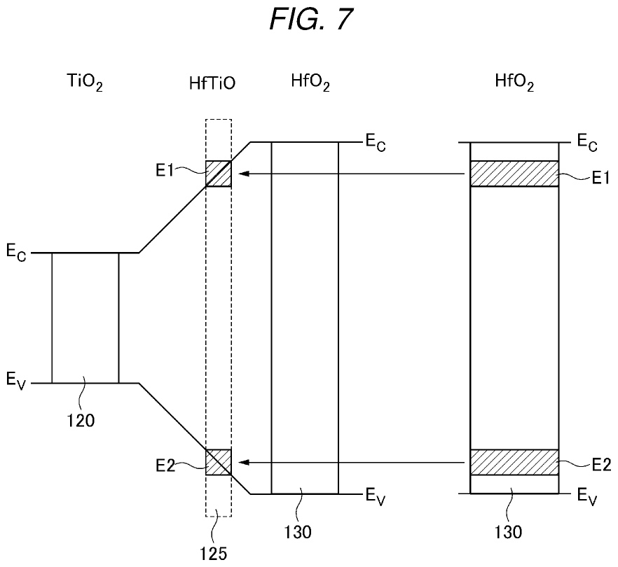

A reason why the electrons “e” easily move to the channel layer 120 when the ferroelectric layer 130 contains the titanium 131 will be described. FIG. 7 schematically shows, for each of titanium oxide (TiO₂) which is contained in the channel layer 120 and hafnia (HfO₂) which is contained in the ferroelectric layer 130, a magnitude of the band gap which is a difference between E_{c} and Eᵥ where E_{c} is energy at a bottom of a conduction band, and Eᵥ is energy at a top of a valence band. As shown in the figure, a band gap of titanium oxide is smaller than a band gap of hafnium. Such a magnitude relationship of the band gap is the same even when, for example, zirconium and the like is used as the material of the ferroelectric layer 130.

When titanium is not contained in the ferroelectric layer 130, the electrons “e” are less likely to move from the ferroelectric layer 130 (HfO₂) to the channel layer 120 (TiO₂) due to the difference in the band gap as described above.

In FIG. 7, a portion denoted by a reference numeral “125” represents a band gap of a portion of the ferroelectric layer 130 (HfO₂) in the vicinity of the boundary on the channel layer 120 (TiO₂) side, that is, a portion which can be regarded as HfTiO containing Ti in HfO₂. This portion is hereinafter also referred to as a “connection portion 125”. In the connection portion 125, E_{c} and Eᵥ change greatly, and the band gap is enlarged from the channel layer 120 (TiO₂) side toward the ferroelectric layer 130 (HfO₂) side.

In such a connection portion 125, E1 and E2, which are new energy levels, are generated by the contained titanium 131. Both of E1 and E2 are lower than E_{c} in the ferroelectric layer 130 (HfO₂) and higher than Eᵥ in the ferroelectric layer 130 (HfO₂).

As a result, as shown in a right end of FIG. 7, in at least the portion of the ferroelectric layer 130 (HfO₂) on the channel layer 120 (TiO₂) side, the levels of E1 and E2 are generated in a range between E_{c} and Eᵥ.

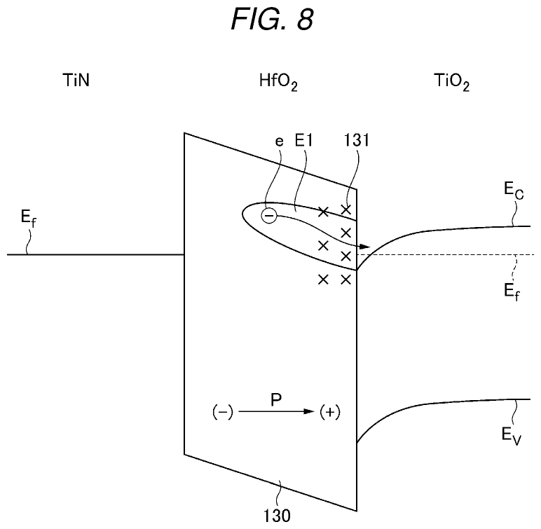

FIG. 8 shows a band diagram including the electrode layers 210 (TiN), the channel layer 120 (TiO₂), and the ferroelectric layer 130 (HfO₂) located between the electrode layers 210 (TiN) and the channel layer 120 (TiO₂). In FIG. 8, spontaneous polarization P in a direction from the electrode layer 210 (TiN) toward the channel layer 120 (TiO₂) is generated in the ferroelectric layer 130 (HfO₂). “E_{f}” shown in the figure is a Fermi level.

As described above, in the portion of the ferroelectric layer 130 (HfO₂) on the channel layer 120 (TiO₂) side, the new level E1 is generated due to the inclusion of the titanium 131. As indicated by an arrow in FIG. 8, the electrons “e” trapped in the ferroelectric layer 130 can move to the channel layer 120 (TiO₂) side via the level E1. Therefore, in the semiconductor storage device 10, the amount of the electrons “e” remaining trapped in the ferroelectric layer 130 can be reduced. By moving holes trapped in the ferroelectric layer 130 to the channel layer via the level E2, accumulation of the holes can be reduced.

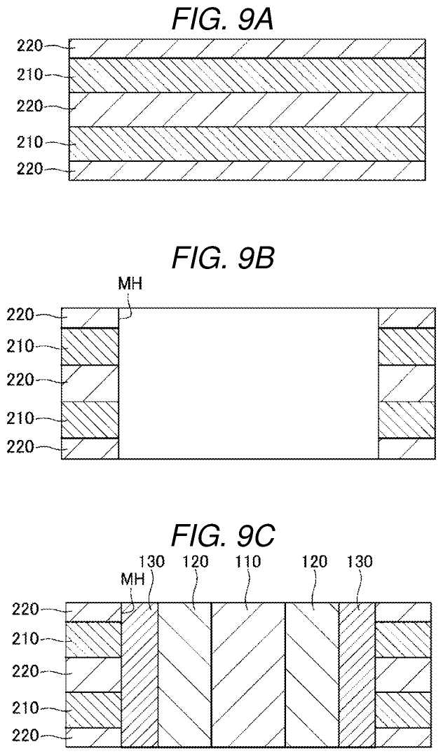

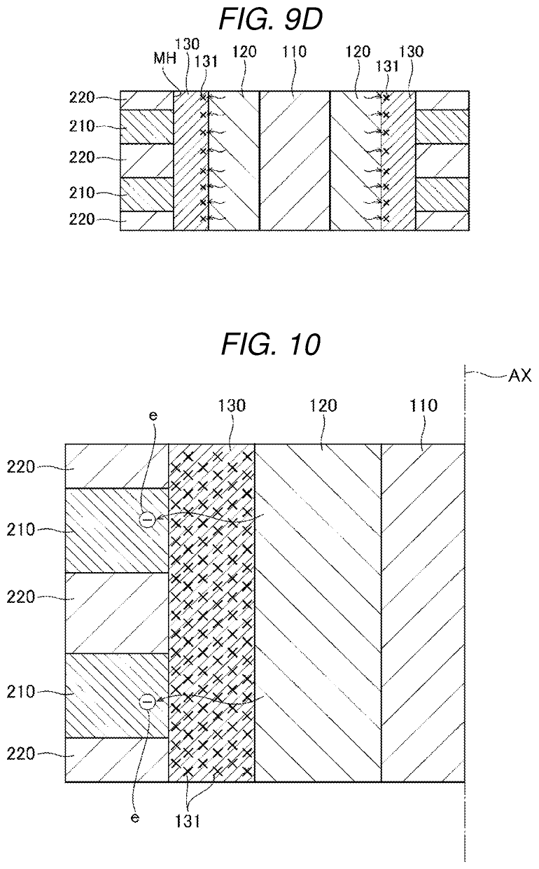

A method of manufacturing the semiconductor storage device 10 will be described with reference to FIGS. 9A to 9D. First, as shown in FIG. 9A, the plurality of electrode layers 210 and the plurality of insulating layers 220 are alternately stacked on a silicon substrate or the like. The electrode layers 210 and the insulating layers 220 can be formed by, for example, CVD (Chemical Vapor Deposition) film formation.

Subsequently, as shown in FIG. 9B, memory holes MH are formed so as to penetrate the stacked electrode layers 210 and the stacked insulating layers 220. The memory holes can be formed by, for example, RIE (Reactive Ion Etching). The memory pillars 100 in FIG. 2 are formed in the memory holes MH.

Subsequently, as shown in FIG. 9C, the ferroelectric layer 130, the channel layer 120, and the core portion 110 are sequentially formed on the inner surface of each memory hole MH. These can be formed by, for example, the CVD film formation.

Subsequently, crystallization annealing is performed by heating as a whole. In a step of the crystallization annealing, the ferroelectric layer 130, the channel layer 120, and the like are heated so as to have a high temperature. Accordingly, both the ferroelectric material in the ferroelectric layer 130 and titanium oxide in the channel layer 120 are crystallized. As described above, the crystal structure of the ferroelectric layer 130 is orthorhombic in at least a part thereof.

At this time, as shown in FIG. 9D, a part of titanium contained in the channel layer 120 (TiO₂) moves to the ferroelectric layer 130 by solid diffusion. Accordingly, as described with reference to FIG. and the like, the ferroelectric layer 130 is in a state of containing the titanium 131 therein. Through the steps described above, the memory cell array 11 of the semiconductor storage device 10 is completed.

Further, in a stage of FIG. 9A, a sacrificial layer made of, for example, silicon nitride may be formed instead of the electrode layer 210. In such a case, after the formation of the memory pillar 100 is completed as shown in FIG. 9C, the sacrificial layer is replaced with the electrode layer 210.

As described above, when the titanium 131 is contained in the ferroelectric layer 130, the charge trapping can be reduced, and the wide memory window can be provided and maintained. However, when a content of the titanium 131 in the ferroelectric layer 130 is too large, another problem may occur. FIG. 10 shows a case where the content of the titanium 131 is too large.

When the content of the titanium 131 in the ferroelectric layer 130 is too large, conductivity of the ferroelectric layer 130 is high, and therefore the electrons “e” easily pass through the ferroelectric layer 130 and flow. That is, a leakage current between the channel layer 120 and the electrode layer 210 increases. As a result, the data cannot be normally stored in the memory cell MC.

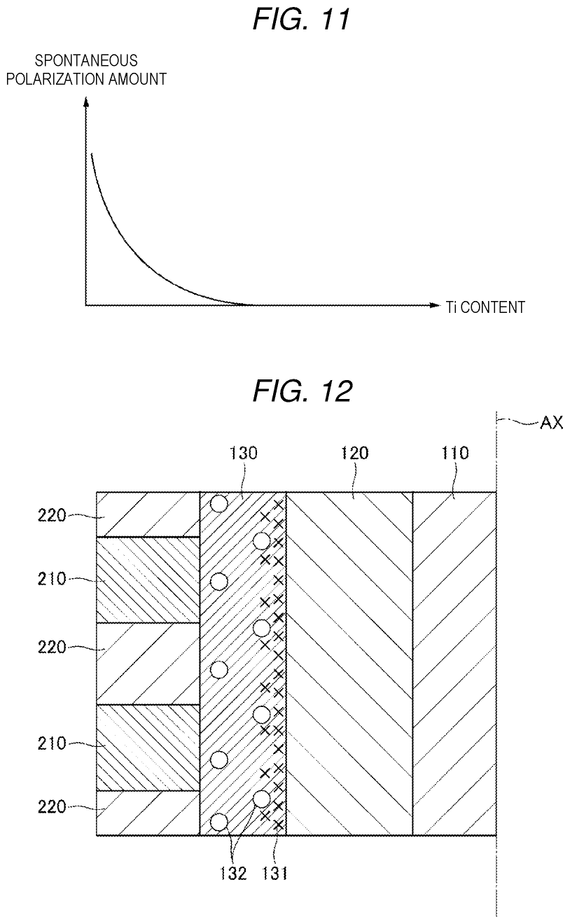

Further, as shown in FIG. 11, when the content of the titanium 131 in the ferroelectric layer 130 increases, the spontaneous polarization amount of the ferroelectric layer 130 decreases. As a result, the ferroelectric layer 130 cannot exhibit a characteristic as a ferroelectric. This also makes it impossible to normally store the data in the memory cell MC.

Therefore, the content of the titanium 131 in the ferroelectric layer 130 is preferably equal to or less than a predetermined value. According to the experiments conducted by the inventors, the content of the titanium 131 per unit volume of the ferroelectric layer 130 is preferably 1% or less of a content of hafnium per unit volume. Here, the “content” is, for example, the number of atoms in a unit volume.

As described above, the ferroelectric layer 130 may contain at least one of hafnium and zirconium. In any case, in the ferroelectric layer 130, the content of the titanium 131 per unit volume is preferably 1% or less of a total content of hafnium and zirconium per unit volume.

The ferroelectric layer 130 may contain other impurity elements in addition to hafnium, zirconium, and oxygen. Examples of such impurity elements include, for example, hydrogen (H), carbon (C), boron (B), chlorine (Cl), fluorine (F), helium (He), and argon (Ar). Among these, when H, C, B, and Cl are contained in the ferroelectric layer 130, a unit cell volume of the orthorhombic crystal in the ferroelectric layer 130 increases. As a result, it is possible to obtain an effect that formation of a monoclinic crystal which is a stable phase is reduced and the memory window is expanded.

H, as an impurity element, is a minimum atom, and has an advantage that H can be introduced at a high concentration. When C is contained in the impurity element, an effect of increasing a crystallization temperature of the ferroelectric layer 130 can also be obtained. F has a relatively high binding energy and is not easily separated from the ferroelectric layer 130. Therefore, when F is added as the impurity element, the characteristic of the ferroelectric layer 130 can be stabilized. Since He and Ar are inert elements, they do not form bonds with other atoms. Therefore, when He and Ar are added as impurity elements, it is possible to obtain an effect that an energy level which causes the leakage current is not formed in the ferroelectric layer 130.

A second embodiment will be described. Hereinafter, features different from the first embodiment will be mainly described, and description of features common to the first embodiment will be appropriately omitted.

In FIG. 12, a semiconductor storage device 10 according to the second embodiment is drawn from the same viewpoint as FIG. 4. The semiconductor storage device 10 includes a ferroelectric layer 130 containing nitrogen 132 dopants in addition to the titanium 131 dopants. The nitrogen 132 may be uniformly distributed in the ferroelectric layer 130, or may be unevenly distributed like the titanium 131.

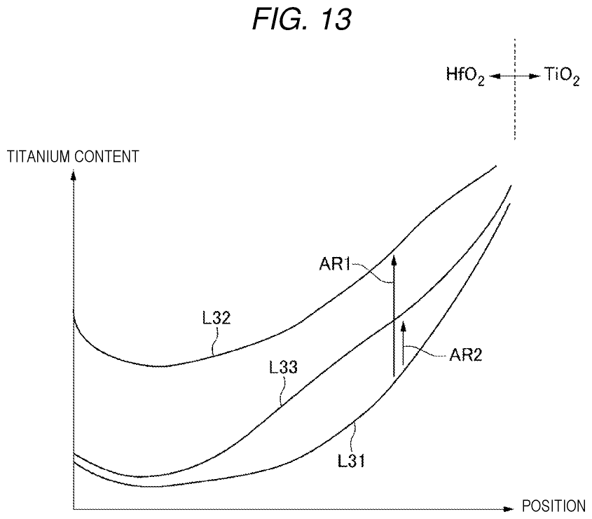

An effect of the nitrogen 132 in the ferroelectric layer 130 will be described. The horizontal axis of a graph shown in FIG. 13 represents positions in the ferroelectric layer 130 (HfO₂). In the graph, a left side along the horizontal axis is the electrode layer 210 side, and a right side is the channel layer 120 (TiO₂) side. The vertical axis of the graph represents a content of the titanium 131 at each position of the ferroelectric layer 130.

A line L31 in FIG. 13 represents distribution of the titanium 131 at a time point before the crystallization annealing in FIG. 9D is performed. When the crystallization annealing is performed in a state where the ferroelectric layer 130 does not contain the nitrogen 132 as in the first embodiment, the distribution of the titanium 131 changes from the line L31 to a line L32 along an arrow AR1. In contrast, when the crystallization annealing is performed in a state where the ferroelectric layer 130 contains the nitrogen 132 as in the second embodiment, the distribution of the titanium 131 changes from the line L31 to a line L33 along the arrow AR1.

As is clear from a comparison between the line L32 and the line L33, when the ferroelectric layer 130 contains the nitrogen 132 (line L33), an increase in the content of the titanium 131 when the crystallization annealing is performed is reduced. That is, when the nitrogen 132 is contained in the ferroelectric layer 130, the amount of the titanium 131 diffused from the channel layer 120 toward the ferroelectric layer 130 can be reduced to an appropriate amount. Accordingly, it is possible to prevent the occurrence of the leakage current shown in FIG. 10. Further, as described with reference to FIG. 11, it is possible to prevent a phenomenon in which the ferroelectric layer 130 cannot exhibit ferroelectric characteristics. A reason why the diffusion of the titanium 131 is reduced is considered to be that continuity of oxygen deficiency in the ferroelectric layer 130 is lost due to the addition of the nitrogen 132.

In order to cause the ferroelectric layer 130 to contain nitrogen, for example, when the ferroelectric layer 130 is formed by CVD film formation as shown in FIG. 9C, a material containing nitrogen (for example, ammonia) may be added. Further, after formation of the ferroelectric layer 130 is completed, nitrogen may be added by plasma and the like.

The above effect obtained by causing the ferroelectric layer 130 to contain nitrogen can be similarly achieved when the ferroelectric layer 130 is formed of a material containing zirconium. The same applies to a case where the ferroelectric layer 130 contains both hafnium and zirconium.

It is confirmed that, in the ferroelectric layer 130, when the number of atoms of nitrogen 132 contained per unit volume is in a range of 1×10¹⁹/cm³ to 5×10²¹/cm³, the above-described effect is particularly easily exhibited.

In the ferroelectric layer 130, the content of the nitrogen 132 per unit volume is preferably within a range of 0.01% to 5% with respect to the total content of hafnium and zirconium per unit volume. Here, the “content” is, for example, the number of atoms in a unit volume.

When the content of the nitrogen 132 falls within any of the above ranges, the diffusion of Ti can be sufficiently reduced. This range is a range in which hopping conduction via impurity atoms does not occur.

Next, a third embodiment will be described. Hereinafter, features different from the first embodiment will be mainly described, and description of features common to the first embodiment will be appropriately omitted.

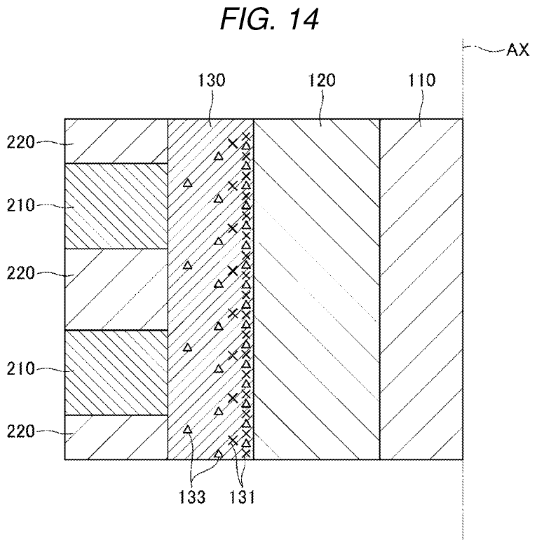

In FIG. 14, a semiconductor storage device 10 according to the third embodiment is drawn from the same viewpoint as FIG. 4. The semiconductor storage device 10 includes a ferroelectric layer 130 formed of an oxide containing zirconium 133 in addition to hafnium.

As shown in FIG. 14, in the ferroelectric layer 130 of the third embodiment, a distribution of the zirconium 133 is biased such that a concentration of the zirconium 133 in a portion on the channel layer 120 side is higher than a concentration of the zirconium 133 in a portion on the electrode layer 210 side.

In such a configuration, since the zirconium 133 is distributed at a higher concentration in the portion on the channel layer 120 side, the amount of the titanium 131 diffused from the channel layer 120 toward the ferroelectric layer 130 is reduced. Accordingly, it is possible to prevent occurrence of a leakage current shown in FIG. 10. Furthermore, as described with reference to FIG. 11, it is possible to prevent a phenomenon in which the ferroelectric layer 130 cannot exhibit ferroelectric characteristics.

Such distribution of the zirconium 133 can be implemented by, for example, changing a component of supplied gas with passage of time when the ferroelectric layer 130 is formed by CVD film formation as shown in FIG. 9C.

Next, a fourth embodiment will be described. Hereinafter, features different from the first embodiment will be mainly described, and description of features common to the first embodiment will be appropriately omitted.

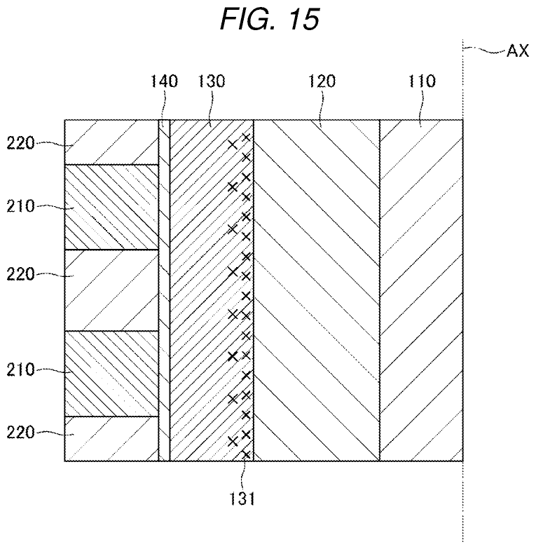

In FIG. 15, a semiconductor storage device 10 according to the fourth embodiment is drawn from the same viewpoint as FIG. 4. As shown in FIG. 15, in the fourth embodiment, an entire surface of the ferroelectric layer 130 on the electrode layer 210 side is covered with an insulating film 140. That is, the insulating film 140 is formed between the ferroelectric layer 130 and the electrode layer 210. In such a configuration, occurrence of a leakage current shown in FIG. 10 can be more reliably prevented by the insulating film 140. As a material of the insulating film 140, a metal oxide such as silicon oxide and aluminum oxide may be used.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a channel layer extending along a first direction and comprising titanium oxide;
an electrode layer extending along a second direction crossing the first direction; and
a ferroelectric layer between the channel layer and the electrode layer and comprising titanium.

2. The semiconductor storage device according to claim 1, wherein the ferroelectric layer comprises an oxide including at least one of hafnium or zirconium.

3. The semiconductor storage device according to claim 2, wherein the ferroelectric layer has an orthorhombic crystal structure.

4. The semiconductor storage device according to claim 2, wherein, in the ferroelectric layer, the amount of titanium per unit volume of the ferroelectric layer is 1% or less of the amount of hafnium and zirconium per unit volume of the ferroelectric layer.

5. The semiconductor storage device according to claim 1, wherein a concentration of titanium in a portion of the ferroelectric layer closer to the channel layer is higher than a concentration of titanium in a portion of the ferroelectric layer closer to the electrode layer.

6. The semiconductor storage device according to claim 1, further including an insulating film between the electrode layer and the ferroelectric layer.

7. The semiconductor storage device according to claim 1, wherein the ferroelectric layer includes nitrogen.

8. The semiconductor storage device according to claim 7, wherein the number of atoms of nitrogen per unit volume is in a range of 1×10¹⁹/cm³ to 5×10²¹/cm³.

9. The semiconductor storage device according to claim 1, wherein
the ferroelectric layer comprises an oxide including hafnium and zirconium, and
a concentration of zirconium in a portion of the ferroelectric layer closer to the channel layer is higher than a concentration of zirconium in a portion of the ferroelectric layer closer to the electrode layer.

10. A semiconductor storage device, comprising:
a channel layer extending along a first direction and comprising titanium oxide;
an electrode layer extending along a second direction crossing the first direction; and
a dielectric layer between the channel layer and the electrode layer, comprising titanium, oxygen, and at least one of hafnium or zirconium, and having an orthorhombic crystal structure.

11. The semiconductor storage device according to claim 10, wherein, in the dielectric layer, the amount of titanium per unit volume of the dielectric layer is 1% or less of the amount of hafnium and zirconium per unit volume of the dielectric layer.

12. The semiconductor storage device according to claim 10, wherein a concentration of titanium in a portion of the dielectric layer closer to the channel layer is higher than a concentration of titanium in a portion of the dielectric layer closer to the electrode layer.

13. The semiconductor storage device according to claim 10, further including an insulating film between the electrode layer and the dielectric layer.

14. The semiconductor storage device according to claim 10, wherein the dielectric layer includes nitrogen.

15. The semiconductor storage device according to claim 14, wherein the number of atoms of nitrogen per unit volume is in a range of 1×10¹⁹/cm³ to 5×10²¹/cm³.

16. The semiconductor storage device according to claim 10, wherein
the dielectric layer comprises hafnium and zirconium, and
a concentration of zirconium in a portion of the dielectric layer closer to the channel layer is higher than a concentration of zirconium in a portion of the dielectric layer closer to the electrode layer.

17. A semiconductor storage device, comprising:
a plurality of first wirings extending along a first direction;
a plurality of second wirings extending along a second direction crossing the first direction; and
a plurality of memory pillars extending along a third direction crossing the first and second directions, each of the memory pillars electrically connected to the second wirings and one of the first wirings and including:
a channel layer comprising titanium oxide, and
a ferroelectric layer outside the channel layer and comprising titanium.

18. The semiconductor storage device according to claim 17, wherein each of the memory pillars includes a core portion including an insulating material inside the channel layer.

19. The semiconductor storage device according to claim 17, wherein one of the second wirings closer to the first wirings extends shorter in the second direction than another of the second wirings farther from the first wirings.

20. The semiconductor storage device according to claim 19, further comprising:
a plurality of contacts extending along the third direction and connected to respective ends of the second wirings in the second direction.
